(19) United States
(12) Patent Application Publication
(10) Pub. No.: US 2023/0413387 A1
(43) Pub. Date: Dec. 21, 2023

(54) HEATER MODULE

(71) Applicant: Dyson Technology Limited, Wiltshire (GB)

(72) Inventors: Chun-Chiu Jonathan LEONG, Chelmsford (GB); Lolan NAICKER, Gloucester (GB)

(73) Assignee: Dyson Technology Limited, Wiltshire (GB)

(21) Appl. No.: 18/038,023

(22) PCT Filed: Nov. 5, 2021
(86) PCT No.: PCT/GB2021/052877

§ 371 Date: May 21, 2023

(30) Foreign Application Priority Data
Dec. 3, 2020 (GB) 2019098.9

(51) Int. Cl. H05B 3/26; H01C 17/23; G01K 7/18

(52) U.S. Cl. CPC H05B 3/265; H01C 17/23; G01K 7/183; H05B 2203/013; H05B 2203/017

(57) ABSTRACT

A heater module includes a heater assembly including a heater and a temperature sensor thermally coupled to the heater, and a trimmable resistor electrically coupled to the temperature sensor or to the heater.

### TECHNICAL FIELD

The invention relates to heating devices, and in particular to thick-film heating elements having embedded temperature sensors.

### BACKGROUND

Thick-film heating elements are compact, offer high heat transfer performance, and can be produced in a variety of shapes. This renders them ideal for many applications, often where heat transfer into a flat contact surface or a fluid flow is required. Such applications range from commercial equipment such as medical and laboratory devices or manufacturing facilities, to consumer appliances such as washing machines, irons, personal care products and beverage dispensers.

FIG. 1 shows the general layout of a basic thick-film heating element 10. The element 10 comprises a rigid plate defining a substrate 12, onto which successive layers, or ‘films’, are formed, the films typically being formed by a series of screen-printing operations. In upward succession from the substrate 12, the films include: an insulation layer 14 defined by a dielectric coating applied to the upper surface of the substrate 12; a heating film 16; and a protective film 18.

The heating film 16 is defined by a heating track, or ‘trace’, namely a continuous, elongate track of conductive material, such as tungsten, formed using metallic ink. The track is formed in a suitable pattern, such as the serpentine shape shown in FIG. 1, to extend through all areas of the surface of the substrate 12. In other examples, multiple heating tracks may be used to similar effect. The heating film 16 is configured to produce heat by the Joule effect on conducting an electrical current. In this respect, the ends of the heating track are exposed to act as contact points to which an electrical voltage may be applied.

The protective film 18 covers the heating film 16 to act as a mechanical shield to protect the heating track from damage and corrosion, in particular to guard against oxidation of the tungsten of the heating trace.

Although the substate 12 has an oblong cross-section in the FIG. 1 example, in practice the substrate 12 is cut to a desired two-dimensional shape to suit each application, this versatility of shape being one of the benefits of using thick-film heating elements.

In this example, the substrate 12 is of stainless steel as is conventional. Hence, the insulating layer 14 is used to separate the heating film 16 from the substrate 12, to isolate the heating trace electrically from the substrate 12. However, if a non-conductive substrate is used the insulating layer 14 may not be required.

In this respect, ceramic-based substrates are beginning to find favour in certain applications, since they can offer higher power density than their metallic counterparts, in that a greater heat output can be achieved for a given surface area. Ceramic substrates can be fabricated as a sintered laminate structure formed from an initial stack of ceramic layers, allowing them to form unique shapes including curves, bends and irregular shapes, which are useful in certain applications and would be significantly more costly to machine from steel, for example. In such arrangements, the protective layer 18 can also be formed from a ceramic layer forming part of the initial stack and co-fired with the other ceramic layers, thereby forming a monolithic ceramic structure in which the heating film 16 is embedded, with only end connector terminals exposed.

Although not illustrated in FIG. 1, it is known to provide metallic substrate based thick-film heating elements with an embedded temperature sensor, such as a glass bead thermistor. Temperature sensors can be used for feedback loop control of the heating element temperature, and optionally to provide a thermal protection function by triggering a device trip in the event of breaching a threshold temperature. However, sensors such as glass bead thermistors are not compatible with processes involving co-firing ceramic stacks, and so it is difficult to integrate such sensors into heating elements having ceramic substrates.

It is against this background that the present invention has been devised.

### SUMMARY OF THE INVENTION

An aspect of the invention provides a heater module, comprising: a heater assembly comprising a heater and a temperature sensor thermally coupled to the heater; and a trimmable resistor electrically coupled to the temperature sensor or to the heater.

The resistance of the trimmable resistor can be adjusted in a predictable and accurate manner using known trimming techniques. This allows the overall resistance, and therefore the performance, of the connected temperature sensor or heater to be controlled with more precision than manufacturing tolerances for the temperature sensor or heater would ordinarily allow.

The heater assembly may be embodied as a thick-film heater element, in which case the temperature sensor comprises a conductor embedded in a substrate of the heater element. The substrate of the heater element may comprise a ceramic material. The trimmable resistor is optionally coupled to the temperature sensor or the heater by vias extending through the substrate. The heater may comprise a conductive trace. Similarly, the temperature sensor may comprise a conductive trace.

The trimmable resistor may be mounted on the heater assembly, for example within a recess in a surface of the heater assembly. If the heater assembly is a thick-film heater element, the recess may be formed into the substrate of the heater element.

Alternatively, the trimmable resistor may be mounted to a discrete resistor module that is configured to connect to the heater assembly. The resistor module may comprise an opening configured to receive a portion of the heating element. The resistor module and the heater assembly may be arranged for interlocking engagement. The trimmable resistor may be connected to the temperature sensor or the heating conductor by wires. Alternatively, or in addition, more direct connection means involving contact points and/or vias may be employed.

The temperature sensor optionally comprises a resistance temperature detector.

The trimmable resistor may comprise at least one trimming cut, which may have been formed by a laser trimming process.

The invention also extends to a personal care device comprising the heater module of the above aspect.

Another aspect of the invention provides a method of manufacturing a heater module, method comprising: bringing a temperature sensor into thermal contact with a heater to form a heater assembly; electrically coupling the temperature sensor to a trimmable resistor; and trimming the trimmable resistor to adjust a combined resistance of the temperature sensor and the trimmable resistor to a predetermined value.

According to a third aspect of the present invention there is provided a heater module comprising a thick-film heating element. The heating element comprises a heating conductor, a temperature sensor, and a substrate supporting the heating conductor and the temperature sensor. The heater module comprises a resistive conductor having at least one trimming cut formed by a trimming process.

The, or each, trimming cut adjusts the resistance of the resistive conductor in a predictable and accurate manner. Accordingly, if the resistive conductor is separate from the temperature sensor or the heating conductor, it can be connected to the temperature sensor or to the heating conductor to add a known resistance to that of the temperature sensor or heating conductor. Alternatively, if the resistive conductor is part of the temperature sensor, or if it is the heating conductor, the trimming cut directly influences the resistance of the temperature sensor or heating conductor. This in turn allows the performance of the temperature sensor or heating conductor to be controlled with more precision than manufacturing tolerances for the temperature sensor or heating conductor would ordinarily allow.

The temperature sensor may comprise a sensing conductor that is electrically coupled to the resistive conductor. Alternatively, the heating conductor may be electrically coupled to the resistive conductor.

The resistive conductor may be mounted on the heating element, and optionally within a recess in a surface of the heating element. The recess may be formed into the substrate of the heating element.

Alternatively, the resistive conductor may be mounted to a discrete resistor module that is configured to connect to the heating element. The resistor module may comprise an opening configured to receive a portion of the heating element.

The heater module may comprise vias configured to couple the resistive conductor electrically to the temperature sensor or the heating conductor.

The resistive conductor may be mounted by soldered joints.

The resistive conductor may comprise a trimmable resistor.

In an alternative approach, the temperature sensor or the heating conductor comprises the resistive conductor. For example, the resistive conductor may be the same feature as the heating conductor, or may represent a sensing conductor of the temperature sensor. In this case, trimming cuts may be applied to the sensing conductor or the heating conductor directly. To allow for this, the heating element may comprise a recess providing external access to a portion of the temperature sensor or the heating conductor including the or each trimming cut.

The substrate of the heating element may comprise a ceramic material.

The heating conductor optionally comprises a conductive trace, for example embodied as a film of the heating element. Similarly, the temperature sensor may comprise a conductive trace.

The temperature sensor may comprise a resistance temperature detector.

The at least one trimming cut may be formed by a laser trimming process.

The invention also extends to a personal care device comprising the heater module of the above aspect.

A fourth aspect of the invention provides a method of manufacturing a heater module comprising a thick-film heating element. The heating element comprises a heating conductor and a temperature sensor supported by a substrate. The method comprises removing material from a resistive conductor of the heater module to increase a total resistance of the temperature sensor and the resistive conductor, or a total resistance of the heating conductor and the resistive conductor, to a predetermined value. The resistive conductor may be the heating conductor, a sensing conductor of the temperature sensor, or a separate conductor to which the heating conductor or temperature sensor are connected, for example.

The method may comprise removing material from the resistive conductor using a trimming process.

In some embodiments, the temperature sensor comprises a sensing conductor that is electrically coupled to the resistive conductor, and the method comprises increasing a combined resistance of the sensing conductor and the resistive conductor to the predetermined value. Alternatively, the heating conductor may be electrically coupled to the resistive conductor, in which case the method comprises increasing a combined resistance of the heating conductor and the resistive conductor to the predetermined value.

The temperature sensor or the heating conductor may comprise the resistive conductor, in which case the resistive conductor may be embodied as a conductive trace of the heating element. In such embodiments, the method comprises trimming the conductive trace to increase the resistance of the trace to the predetermined value.

It will be appreciated that preferred and/or optional features of each aspect of the invention may be incorporated alone or in appropriate combination in the other aspects of the invention also.

### BRIEF DESCRIPTION OF THE DRAWINGS

FIG. 1 shows a known thick-film heating element and has already been described. One or more embodiments of the invention will now be described, by way of example only, with reference to the remaining drawings, in which like features are assigned like numerals, and in which:

FIG. 2 is a stacked bar chart demonstrating principles of the invention;

FIG. 3 shows a tuning resistor for use in embodiments of the invention;

FIG. 4 shows example trimming patterns to be used with the tuning resistor of FIG. 3;

FIG. 5 shows a heating element suitable for use in embodiments of the invention;

FIG. 6 is a detail view of part of the element of FIG. 5 including the resistor of FIG. 3;

FIG. 7 shows an alternative embodiment in which a tuning resistor is mounted to a discrete tuning module to be connected to a heating element; and

FIG. 8 shows a detail view of a heating element according to another embodiment of the invention.

### DETAILED DESCRIPTION

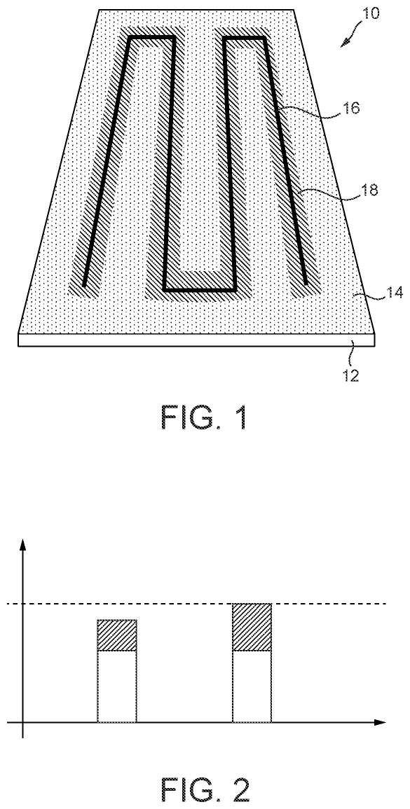

In general terms, embodiments of the invention provide heater modules including thick-film heating elements, for example such as that illustrated in FIG. 1, but having embedded sensor arrangements with precise resistance values of an accuracy sufficient to allow for their use in thermal protection applications. The embedded sensor arrangement is typically in the form of a further film defining a resistance temperature detector (RTD) trace.

For a temperature sensor to act as a thermal protection device, its performance must adhere to relevant regulatory standards. This typically entails achieving thermistor classification for the temperature range of interest, in particular the threshold trip temperature.

However, the mass manufacture of thick-film heating elements is highly prone to error and so manufacturing tolerances tend to be relatively large. For example, a resistance variability of plus or minus 15% is common for a heating element film, which is inadequate for the purposes of thermal protection and may also fail to satisfy EMC (electromagnetic compatibility) requirements. Whilst screen-printing processes can be optimised for each application to some extent, this entails a lengthy development process and with no guarantee of achieving the required outcome.

In view of these challenges, instead of attempting to improve the precision with which thick-film heating elements are manufactured, embodiments of the invention take an approach in which the usual manufacturing tolerances are accepted and adjustments are made to the element after it has been produced to achieve the required performance.

This entails adjusting the fabrication process to shift the relevant manufacturing tolerance bands relating to the resistance of the RTD trace, such that the upper limit of the manufacturing tolerance for the RTD trace resistance is below or coincides with the required resistance value. In other words, the RTD trace is deliberately manufactured with a resistance at, or usually below, its target value. Then, the resistance of the RTD trace is brought up to the required value using one of two approaches.

In the first approach, an additional tuning resistor is connected to the RTD trace such that the tuning resistor and the heating element together form a heater module. The tuning resistor is trimmable or otherwise adjustable such that its resistance can be modified to yield the required combined resistance from the RTD trace and the resistor at the relevant temperature, for example the threshold temperature at which a trip will occur. The tuning resistor may have a similar temperature-resistance relationship to the main RTD trace, but more likely has a resistance that is substantially insensitive to temperature. Accordingly, the temperature-resistance characteristics of the assembly of the resistor and the RTD trace are dominated by the temperature response of the RTD trace, but with a generally constant offset created by the tuning resistor.

The tuning resistor may be mounted directly onto the heating element, or alternatively the resistor may be integrated into a separate resistor module that is arranged to couple to the heating element in a manner that creates electrical continuity between the tuning resistor and the RTD trace, in which case the resistor module also forms part of the heater module.

In the second approach, part of the embedded RTD trace may be exposed, for example by creating a recess, or ‘window’, in the surrounding material, such that the trace can be trimmed or otherwise ablated directly to increase its resistance. In such arrangements, the heating element including the additional feature of trimming cuts to the RTD trace defines the ‘heater module’. The window is typically created by a punching machine that removes material from the ceramic stack to define the window in the ‘greenline’ stage of manufacture, prior to firing and sintering the stack.

The general principle is illustrated in FIG. 2, which shows two stacked bar plots corresponding to the first approach in which a tuning resistor is coupled to the RTD trace to define a heater module. Each bar plot represents the resistance of the RTD trace and the tuning resistor relative to a target resistance denoted by a horizontal dashed line. Each of the plots is a stack having a lower segment and an upper segment. The lower segment represents the resistance of the RTD trace, this resistance being identical for both plots as the RTD trace itself is not modified in this example. The upper segment indicates the resistance of the tuning resistor. The overall height of the bar plot therefore indicates the combined resistance of the RTD trace and the tuning resistor.

The plot shown to the left in FIG. 2 represents the initial state, in which the combined resistance of the RTD trace and the tuning resistor is below the target resistance. It is noted that the resistance of the RTD trace is therefore not only below the target value, but is sufficiently below the target value that the combined resistance of the RTD trace and the tuning resistor remains below the target value, accounting for the maximum initial resistance of the tuning resistor.

The plot shown to the right in FIG. 2 shows the situation after the tuning resistor has been trimmed to increase its resistance, such that the combined resistance of the RTD trace and resistor assembly equals the target resistance. Whilst in practice the combined resistance may not perfectly equal the target, it will be within a margin of error that is substantially smaller than the corresponding margin for the initial RTD trace alone. Accordingly, using this approach enables the final resistance of the temperature sensing components of the heating element to be controlled more precisely than is typically possible using standard thick-film manufacturing processes.

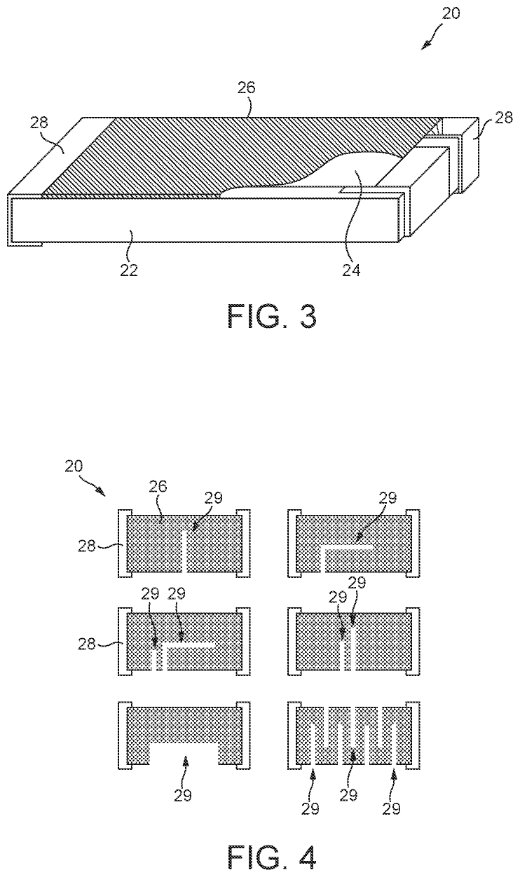

FIG. 3 shows an example of a tuning resistor 20 to be used in such an approach, which conveniently is an off-the-shelf trimmable resistor in this example and is similar in structure to a thick-film chip resistor. Such resistors are not only adjustable but can also withstand the temperatures to which they will be exposed when used with a thick-film heating element. In contrast, standard resistors typically would not have such thermal compatibility.

The bulk of the tuning resistor 20 is defined by a cuboidal substrate 22 of ceramic. An upper surface of the substrate 22 bears a resistive layer 24, typically of aluminium oxide, which in turn is covered by a protective overglaze 26, the resistive layer 24 and the overglaze 26 being formed by screen-printing in successive stages. The overglaze 26 is typically formed from a glass encapsulant composition such as DuPont QQ620, all registered trade marks being acknowledged.

U-shaped metallic end terminations 28 slide over each end of the substrate 22 and are in electrical contact with the resistive layer 24, such that the electrical resistance between the terminations 28 is defined by the properties of the resistive layer 24. Accordingly, the overall resistance of the tuning resistor 20, namely the resistance presented between the terminations 28, can be varied by modifying the resistive layer 24, specifically by removing material from the resistive layer 24 using an ablation process or similar, which is referred to as ‘trimming’ the resistor 20.

FIG. 4 shows some typical trimming patterns that may be cut into the resistive layer 24 of the tuning resistor 20 to adjust its overall resistance between the terminations 28, each trimming pattern comprising one or more continuous cuts 29, or ‘kerfs’. In general terms, trimming the tuning resistor 20 increases its resistance by altering the characteristics of a conductive path defined between the end terminations 28, in particular by extending that path and by adding complexity to the shape of the path. The skilled person will appreciate that the impact that each trimming pattern has on the overall resistance of the tuning resistor is a function of: the number of kerfs 29; the length and thickness of each kerf 29; and the shape of each kerf 29. For example, the inclusion of a right-angle in the kerf 29 of the pattern 29 shown in the upper right of FIG. 4, which is commonly referred to as an ‘L-cut’, will add resistance in addition to that created by the effect of the length of the cut 29.

The trimming patterns shown in FIG. 4, or indeed any suitable trimming pattern, can be formed in a variety of ways, including laser trimming, anodisation, heat trimming, electrical trimming, mechanical trimming and chemical trimming. These techniques are known from the microelectronics industry and so will not be described in detail here to avoid obscuring the invention.

Taking the example of laser trimming briefly, a continuous kerf 29 is formed progressively into the material of the resistive layer 24 by a concentrated beam of light of a few microns in diameter, the energy of which is absorbed by the resistive material, causing that material to vaporise. The changing resistance of the tuning resistor 20 can be monitored while the cut 29 is being made, with the trimming operation being terminated once the target value is reached. Feedback-controlled trimming equipment is available for this purpose. The accuracy of the final resistance of the tuning resistor 20 is therefore dependent on the speed at which the trimming process can be terminated.

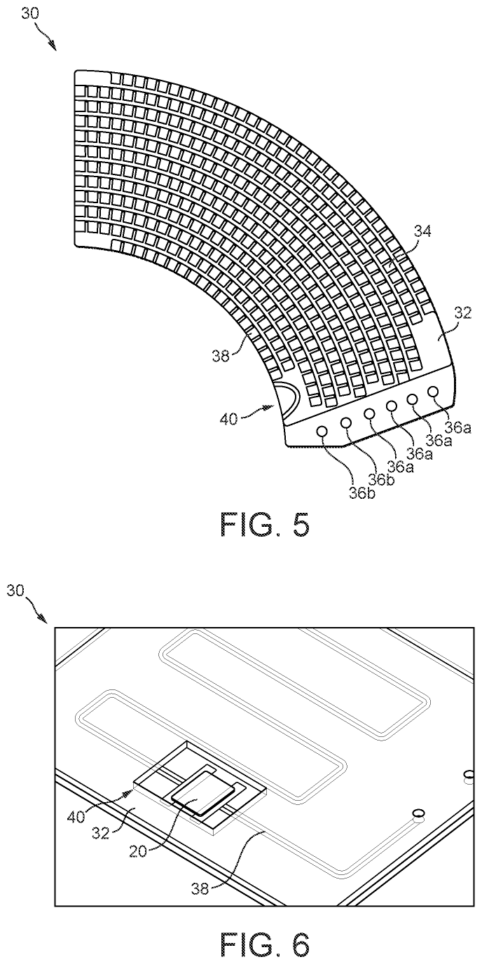

The tuning resistor 20 can be incorporated either by mounting it directly onto a heating element 10, or as part of a tuning module that is connected to a heating element 10. Examples of these different approaches are described below with reference to FIGS. 5 to 8.

FIG. 5 shows a thick-film heating element 30 that is suitable for use with tuning resistors in embodiments of the invention. The heating element 30 of FIG. 5 is structurally similar to the conventional heating element 10 of FIG. 1 that has already been described, and so the description of the element of FIG. 5 will concentrate on features that differ from the element 10 of FIG. 1. It is noted, however, that the heating element 10 of FIG. 1 could also be used in embodiments of the invention, which in general terms can be applied to any thick-film heating element.

The heating element 30 shown in FIG. 5 has a ceramic substrate 32 onto which a series of films are formed as in the FIG. 1 example, the substrate 32 being curved in a plane in which the films of the element 30 extend. This curvature is determined to optimise the heating element 30 for its intended application, which in this example is as a heater for a personal care device such as a hair drying device. The curvature of the heating element 30 corresponds to a path along which air flows through the device, thereby maximising the effectiveness of heat transfer into that air flow.

The heating element 30 of FIG. 5 has a heating trace 34 that is served by a set of four end terminals 36 arranged along a lower end of the element 30, as viewed in FIG. 5, along with an embedded RTD trace 38 that adds a further pair of terminals 36. Accordingly, a series of six terminals 36 extends along the lower end of the heating element 30.

The four terminals 36 associated with the heating trace 34 define heating terminals 36a, and include a common live terminal, which is that shown furthest to the right in FIG. 5, and three neutral terminals, which appear in succession moving leftward from the live terminal. All four of these heating terminals 36a connect to an embedded conductor of tungsten defining the heating trace 34, which is embedded within the ceramic substrate material of the element 30 and extends in a single plane along a serpentine path that follows the curvature of the heating element 30 and repeats on itself to define several parallel sections of the heating trace 34 that appear as rows in FIG. 5. Some portions of the heating trace 34 are exposed, for example to enable connections to be made to the heating terminals 36a. These exposed portions are provided with a protective nickel coating that is applied after the surrounding ceramic has been fired, to protect against corrosion and also to assist with creating the electrical connections to the heating terminals 36a.

When electrical power is supplied to the heating terminals 36a, the heating trace 34 generates heat by the Joule effect. That heat is evenly spread across the surface of the heating element 30 and so can be transferred effectively to air flowing across that surface.

The final pair of terminals, shown furthest to the left in FIG. 5, are connected to the RTD trace 38 and so define RTD terminals 36b. The RTD trace 38 is similar to the heating trace 34 in that it is defined by a conductor of the same material, namely tungsten with a protective nickel coating, the conductor being embedded within the ceramic material and extending through the heating element 30 in a serpentine path back-and-forth along the length of the heating element 30. However, instead of supplying electrical power to the RTD terminals 36b, the electrical resistance across the RTD terminals 36b is measured to provide an indication of the temperature of the heating element 30.

The tuning resistor 20 must be electrically coupled to the RTD trace 38 to impact the resistance of the RTD trace 38, and FIG. 5 indicates the location of a window 40 formed for this purpose into the ceramic in which the RTD trace 38 is embedded. FIG. 6 provides a detail perspective view of the window 40, with the substrate 32 rendered transparent to reveal the RTD trace 38 within.

As FIG. 6 reveals, the window 40 is defined by a recess of sufficient size to accommodate the tuning resistor 20, the window 40 being formed into the ceramic material of the heating element 30 down to the level of the film containing the RTD trace 38, to expose the conductive material of the RTD trace 38. The position of the window 40 shown in FIG. 5 locates it conveniently near to the terminal ends of the RTD trace 38, although in principle the resistor 20 could couple to any part of the RTD trace 38.

The resistor 20 is aligned with the path of the RTD trace 38 such that the RTD trace 38 passes beneath a centreline of the resistor 20, with each end termination 28 of the resistor resting directly on the RTD trace 38. Brazed connections couple the end terminations 28 electrically and permanently to respective spaced points of the RTD trace 38. Accordingly, the tuning resistor 20 extends parallel to and above a short section of the RTD trace 38 to define a sensing assembly comprising both the resistor 20 and the RTD trace 38. The sensing assembly has a greater overall resistance than the RTD trace 38 alone and, more importantly, can be tuned to a more precise resistance than could be achieved for the RTD trace 38 alone using ordinary thick-film processes.

In this respect, the tuning resistor 20 can be trimmed prior to mounting it on the heating element 30. This will entail taking separate measurements of the resistance of the RTD trace 38 and the tuning resistor 20 at the target temperature, and then trimming the tuning resistor 20 as necessary to increase its resistance at the target temperature such that, when combined with the measured resistance of the RTD trace 38, the overall resistance of the sensing assembly is equal to, or within a predefined tolerance band of, the target resistance. Alternatively, the tuning resistor 20 can be trimmed in situ on the heating element 30 after it has been fitted, which conveniently allows the overall resistance of the sensing assembly, which is the variable of interest, to be measured directly during the trimming procedure. Trimming the tuning resistor 20 in situ also inherently accounts for any impact on the overall resistance of the sensing assembly caused by the soldered joints between the terminations 28 of the tuning resistor 20 and the RTD trace 38.

Whether the tuning resistor 20 is trimmed in advance or in situ, the trimming process follows the general principles outlined above with respect to FIG. 2, optionally employing one or more of the trimming patterns shown in FIG. 4.

Significant heat may be generated in the tuning resistor 20 during the trimming process. This must be accounted for when the tuning resistor 20 is trimmed in situ, as the heat could impact the integrity of the soldered connections between the terminations 28 of the tuning resistor 20 and the RTD trace 38. For example, the speed of the trimming operation may be adjusted to avoid heating the tuning resistor 20 to an extent that could risk melting of the soldered joints. Also, the atmosphere in which the resistor 20 is trimmed may be modified to minimise the impact of heat generated in the trimming process.

Once the tuning resistor 20 is installed and the combined resistance of the RTD trace 38 and the tuning resistor 20 has been tuned to the relevant predetermined value, a protective covering may be applied over the tuning resistor 20 to shield the resistor 20 and any exposed portions of the RTD trace 38 from damage and corrosion thereafter, for example to guard against oxidation of the tungsten of the RTD trace 38. The protective covering may be created by plating the relevant area, for example using a nickel-boron (NiB) coating.

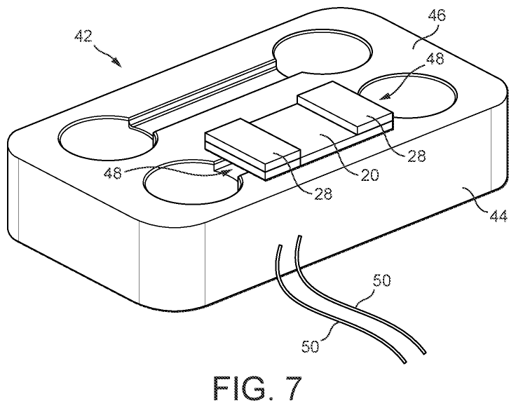

FIG. 7 shows an alternative approach, in which a tuning resistor 20 is not mounted directly onto the heating element 30, but is instead incorporated into a separate tuning module 42 that is arranged to couple to the heating element 30 in a plug-and-socket arrangement to establish electrical communication between the tuning resistor 20 and the RTD trace 38 of the heating element 30. The assembly of the heating element 30 and the tuning module 42 therefore defines a heater module in this example.

The skilled reader will appreciate that there are various ways in which such an arrangement might be implemented, and the example shown in FIG. 7 is greatly simplified for the purposes of illustrating the concept. In this example, the tuning module 42 defines a female part of a male-female interface between the module and the heating element 30. In other arrangements, the tuning module 42 and the heating element 30 may engage in a different way and indeed may not engage directly at all, but instead be connected by wires.

In this respect, the tuning module 42 comprises a cuboid tuning module body 44, an upper surface 46 of which supports the tuning resistor 20. It will be appreciated that the shape of the tuning module 42 can be adjusted to suit each application, however. A front surface of the tuning module body 44 extending in a plane orthogonal to that of the upper surface 46 supporting the tuning resistor 20 includes a recess (not shown) arranged to admit an end of the heating element 30, or a suitable protruding portion of the heating element 30. The recess is therefore of a size and shape corresponding to the cross-section of the corresponding part of the heating element 30, and is of a depth sufficient that the received part of the heating element 30, when fully inserted, lies directly beneath the tuning resistor 20.

A pair of spaced vias extend between the upper surface 46 of the tuning module body 44 and the interior of the recess, each via comprising an electrical contact point 48 at each end and a conductive path extending between the contact points 48 through the material of the tuning module body 44. Each end termination 28 of the tuning resistor 20 is fixed by a brazed connection to a contact point 48 of a respective one of the vias on the upper surface 46, whilst the contact points on the interior of the recess define respective inner terminals, each of which is therefore electrically connected to a respective one of the end terminals of the tuning resistor 20.

Correspondingly, the end of the heating element 30 is provided with a pair of windows similar to the window 40 of the arrangement shown in FIG. 6, each window being positioned to align with a respective inner terminal when the heating element 30 is fully inserted into the tuning module 42. Each window exposes a portion of the RTD trace 38, to enable connection of that portion of the RTD trace 38 to the respective aligned inner terminal. For example, the inner terminals may comprise spring-loaded contact pins arranged to engage the exposed portions of the RTD trace 38 beneath them.

In this way, the end terminations 28 of the tuning resistor 20 are electrically connected to the RTD trace 38, to create an equivalent sensing assembly to that of the arrangement shown in FIG. 6, namely a sensing assembly defined by the combination of the RTD trace 38 and the tuning resistor 20.

The tuning module 42 further includes electrical contact points within the recess that are arranged to engage the RTD terminals 36b of the heating element 30 (not shown in FIG. 7), those contact points communicating electrically with wires 50 extending from the rear of the tuning module 42. The combined electrical resistance of the RTD trace 38 and the tuning resistor 20 can therefore be measured using the wires 50, to provide an indication of the temperature of the heating element 30 in use.

Using the tuning module 42 of FIG. 7, the tuning resistor 20 can be trimmed in situ, in advance or, if necessary, in stages. In this respect, trimming processes are sufficiently well-controlled that it is typically only necessary to perform a single trimming operation with reference to a measured initial resistance to achieve the required final resistance. This single trim is typically performed with the heating element 30 and the tuning module 42 connected.

However, trimming in stages is possible if required, in that the tuning module 42 can be removed for an initial trimming operation, reconnected to the heating element 30 to test the combined resistance of the RTD trace 38 and tuning resistor 20, and then removed again to make adjustments by further trimming as may be necessary. This flexibility in terms of the different ways in which the tuning module 42 can be tuned, which derives from the mechanical and reconnectable nature of the connection between the tuning resistor 20 and the RTD trace 38 created using the tuning module 42, may be beneficial in certain contexts.

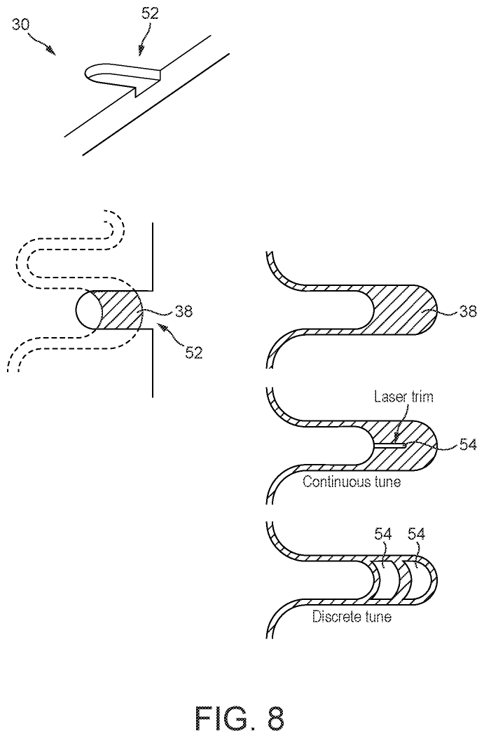

Turning finally to FIG. 8, the alternative approach to tuning the resistance of the RTD trace 38 is shown, in which a tuning resistor is not required and the RTD trace 38 itself is processed to modify its resistance at the temperature of interest, for example a trip temperature. As FIG. 8 shows, this involves creating a window 52 in the material of the heating element 30 to expose the RTD trace 38 in a similar manner as for the approaches shown in FIGS. 5 to 7, and then trimming or otherwise ablating the exposed RTD trace 38 material directly. This may entail creating a single continuous trimming cut 54 or a series of discrete cuts 54 to achieve the desired result. The heating element 30 with the trimmed RTD trace 38 defines a heater module in this arrangement.

A continuous trim influences both the effective width and the length of the RTD trace 38, and so the impact on resistance can be characterised as follows:

$$R = ρ \frac{L}{A} = ρ \frac{L}{W \cdot t} - \frac{ρ}{t} [ \frac{L}{W} ]$$

In addition, discrete trims create parallel conductive paths and so further impact resistance according to the following equation:

$$\frac{1}{{R}_{TOTAL}} = \frac{1}{{R}_{1}} + \frac{1}{{R}_{2}} + \frac{1}{{R}_{3}} + … ,$$

In general terms, trimming the RTD trace 38 directly follows the same principles as for trimming a tuning resistor, albeit potentially being more difficult to perform accurately in practice. There may also be some uncertainty regarding the compatibility of the resistive ink used for the RTD trace 38 and the substrate material with the trimming process, in contrast with using a separate tuning resistor having an aluminium oxide resistive layer whose properties are well characterised.

Another potential drawback of trimming the RTD trace 38 directly is that if the trimming process is unsuccessful, for example because the RTD trace 38 resistance increases too far, the entire heating element 30 may have to be discarded. In contrast, in approaches involving a tuning resistor, only the tuning resistor must be replaced in the event of an error in the trimming process.

It will be appreciated that various changes and modifications can be made to the present invention without departing from the scope of the present application.

For example, although the above description refers to adjusting the resistance of an RTD trace using a tuning resistor or by trimming the trace directly, the same principles can be applied in a corresponding manner to adjusting the resistance of a heating trace, for example to alter the power output of the heating trace and therefore refine performance. Accordingly, the performance of a heating trace can be modified as may be desired by trimming the heating trace directly, or by connecting the heating trace to a tuning resistor and trimming the resistor to achieve the required overall resistance.

Where trimming techniques are used with heating traces, it should be noted that power will be dumped around each trimming feature when the trace is in use, producing localised heating spikes. These hot zones must be accounted for, in particular to ensure that any brazed joints will not be compromised by such heating effects.

Trimming features may be added to both an RTD trace and a heating trace in a given heating element. For example, a tuning module to be connected to a heating element may include a respective tuning resistor for each trace.

1. A heater module, comprising:
a heater assembly comprising a heater and a temperature sensor thermally coupled to the heater; and
a trimmable resistor electrically coupled to the temperature sensor or to the heater wherein the heater assembly is embodied as a thick-film heater element, and wherein the temperature sensor comprises a conductor embedded in a substrate of the heater element.

2. The module of claim 1, wherein the substrate of the heater element comprises a ceramic material.

3. The module of claim 1, wherein the trimmable resistor is coupled to the temperature sensor by vias extending through the substrate.

4. The module of claim 1, wherein the heater comprises a conductive trace.

5. The module of claim 1, wherein temperature sensor comprises a conductive trace.

6. The module of claim 1, wherein the trimmable resistor is mounted on the heater assembly.

7. The module of claim 6, wherein the trimmable resistor is mounted within a recess in a surface of the heater assembly.

8. The module of claim 7, wherein the recess is formed into the substrate of the heater element.

9. The module of claim 1, wherein the trimmable resistor is mounted to a discrete resistor module that is configured to connect to the heater assembly.

10. The module of claim 9, wherein the resistor module comprises an opening configured to receive a portion of the heating element.

11. The module of claim 9, wherein the resistor module and the heater assembly are arranged for interlocking engagement.

12. The module of claim 9, wherein the trimmable resistor is connected to the temperature sensor or the heating conductor by wires.

13. The module of claim 1, wherein the temperature sensor comprises a resistance temperature detector.

14. The module of claim 1, wherein the trimmable resistor comprises at least one trimming cut.

15. The module of claim 14, wherein the at least one trimming cut is formed by a laser trimming process.

16. A personal care device comprising the heater module of claim 1.

17. A method of manufacturing a heater module, method comprising:
bringing a temperature sensor into thermal contact with a heater to form a heater assembly;
electrically coupling the temperature sensor to a trimmable resistor; and
trimming the trimmable resistor to adjust a combined resistance of the temperature sensor and the trimmable resistor to a predetermined value.
